(19) United States
(12) Patent Application Publication
(10) Pub. No.: US 2026/0290275 A1
(43) Pub. Date: Sep. 24, 2026

(54) ARRAY SUBSTRATE, DISPLAY SUBSTRATE, AND DISPLAY DEVICE

(71) Applicants: Wuhan BOE Optoelectronics Technology Co., Ltd., Wuhan (Hubei) (CN); BOE TECHNOLOGY GROUP CO., LTD., Beijing (CN)

(72) Inventors: Bin XIE, Beijing (CN); Yujie GAO, Beijing (CN); Xinxin ZHAO, Beijing (CN); Zhi YANG, Beijing (CN); Jing WANG, Beijing (CN); Shi CHENG, Beijing (CN); Zimo SHENG, Beijing (CN); Xiangyu GAO, Beijing (CN); Jun FENG, Beijing (CN); Junjie FU, Beijing (CN); Wei WU, Beijing (CN)

(73) Assignees: Wuhan BOE Optoelectronics Technology Co., Ltd., Wuhan (Hubei) (CN); BOE TECHNOLOGY GROUP CO., LTD., Beijing (CN)

(21) Appl. No.: 19/475,484

(22) PCT Filed: May 29, 2024
(86) PCT No.: PCT/CN2024/096163

§ 371 Date: Oct. 15, 2025

(30) Foreign Application Priority Data
May 31, 2023 (CN) 202310638452.1

(51) Int. Cl. G09G 3/36

(52) U.S. Cl. CPC G09G 3/3677; G09G 2300/0426

(57) ABSTRACT

Provided are an array substrate, a display substrate and a display device. The array substrate includes: a substrate, a driving circuit layer on a side of the substrate and including: gate driving circuits in a first frame region extending in a first direction, a first signal line and a second signal line extending in the first direction, and a third signal line extending in a second direction. The first signal line is on a side of the second signal line away from a driving region. The gate driving circuits include a dummy gate driving circuit and a starting row gate driving circuit; an end of the first signal line is electrically connected to the third signal line, the other end is electrically connected to a driving chip. The third signal line is electrically connected to the dummy gate driving circuit and the starting row gate driving circuit.

### CROSS-REFERENCE TO RELATED APPLICATION(S)

This application is a Section 371 National Stage Application of International Application No. PCT/CN2024/096163 filed on May 29, 2024, which claims priority to Chinese Patent Application No. 202310638452.1 filed on May 31, 2023, the whole contents of which are incorporated herein by reference in their entireties.

### TECHNICAL FIELD

The present disclosure relates to display technologies, and in particular to an array substrate, a display substrate and a display device.

### BACKGROUND

A display panel includes a driving circuit layer and a light-emitting structure layer on the driving circuit layer. The driving circuit layer includes a gate driving circuit and a pixel circuit. A starting row gate driving circuit receives a driving signal provided by a driving chip, outputs the driving signal to the pixel circuit, and outputs a cascaded signal to a cascaded gate driving circuit.

### SUMMARY

Provided are an array substrate, a display substrate and a display device.

According to a first aspect of embodiments of the present disclosure, an array substrate is provided, including a driving region and a first frame region located on a side of the driving region and extending in a first direction, the array substrate includes: a substrate; and a driving circuit layer on a side of the substrate, including: a plurality of gate driving circuits in the first frame region, the plurality of gate driving circuits include a dummy gate driving circuit and a starting row gate driving circuit; a first signal line and a second signal line, the first signal line and the second signal line extend in the first direction, and the first signal line is located on a side of the second signal line away from the driving region; and a third signal line extending in a second direction, the second direction intersects the first direction, an end of the first signal line is electrically connected to the third signal line, the other end of the first signal line is configured to be electrically connected to a driving chip, the driving chip provides a driving signal to the starting row gate driving circuit, the third signal line is electrically connected to the dummy gate driving circuit and is electrically connected to the starting row gate driving circuit.

In an embodiment, the driving circuit layer further includes: a fourth signal line adjacent to the first signal line, the fourth signal line is disposed in a same layer and extends in a same direction as the first signal line, and the fourth signal line is connected to the third signal line; and a lapping portion overlapped with the first signal line and the fourth signal line, respectively.

In an embodiment, the driving circuit layer includes: a first conductive layer; a first insulating layer located on a side of the first conductive layer away from the substrate; a second conductive layer located on a side of the first insulating layer away from the substrate; and a second insulating layer located on a side of the second conductive layer away from the substrate, and the first signal line and the fourth signal line are located in the first conductive layer, and the lapping portion is located on a side of the first insulating layer facing the substrate.

In an embodiment, the driving circuit layer includes: a first conductive layer; a first insulating layer located on a side of the first conductive layer away from the substrate; a second conductive layer located on a side of the first insulating layer away from the substrate; and a second insulating layer located on a side of the second conductive layer away from the substrate, and the first signal line and the fourth signal line are located in the first conductive layer, the first insulating layer is provided with a first through hole, and the lapping portion is located on a side of the second insulating layer facing the substrate and is located in the first through hole.

In an embodiment, the driving circuit layer includes: a first conductive layer; a first insulating layer located on a side of the first conductive layer away from the substrate; a second conductive layer located on a side of the first insulating layer away from the substrate; and a second insulating layer located on a side of the second conductive layer away from the substrate, and the first signal line and the fourth signal line are located in the first conductive layer, the driving circuit layer is provided with a second through hole penetrating the first insulating layer and the second insulating layer, and the lapping portion is located in the second through hole.

In an embodiment, the fourth signal line includes a first sub-signal line, a second sub-signal line and a third sub-signal line disposed in the first direction; and a first gap is provided between the second sub-signal line and the first sub-signal line and between the second sub-signal line and the third sub-signal line, respectively, and the second sub-signal line is lapped with the lapping portion and is connected to the third signal line.

In an embodiment, the third signal line includes a fourth sub-signal line and a fifth sub-signal line located on a side of the fourth sub-signal line away from the first signal line; and a second gap is provided between the fourth sub-signal line and the fifth sub-signal line, an end portion of the fourth sub-signal line away from the second gap is electrically connected to the first signal line, and an end portion of the fourth sub-signal line adjacent to the second gap is electrically connected to the starting row gate driving circuit.

In an embodiment, the driving circuit layer further includes a first wire, an end of the first wire is connected to the third signal line, and the other end of the first wire is electrically connected to the starting row gate driving circuit; and the array substrate further includes an insulating layer located between the first wire and the third signal line, the first wire is electrically connected to the third signal line through an opening on the insulating layer, and an orthographic projection of the first wire on the substrate overlaps with an orthographic projection of the third signal line on the substrate.

In an embodiment, the driving circuit layer further includes a first wire, and the first wire includes a first sub-wire and a second sub-wire; an end of the first sub-wire is connected to the third signal line, and the other end of the first sub-wire is electrically connected to the starting row gate driving circuit; the second sub-wire is located on a side of the first sub-wire away from the starting row gate driving circuit; and a third gap is provided between the first sub-wire and the second sub-wire.

In an embodiment, the driving circuit layer further includes a first wire and at least one fifth signal line; an end of the first wire is connected to the third signal line, the other end of the first wire is electrically connected to the starting row gate driving circuit, and the first wire extends at least partially in the first direction; the fifth signal line extends in the second direction and is electrically connected to the dummy gate driving circuit; and the fifth signal line includes a sixth sub-signal line, a seventh sub-signal line and an eighth sub-signal line disposed in the second direction, a fourth gap is provided between the seventh sub-signal line and the sixth sub-signal line and between the seventh sub-signal line and the eighth sub-signal line, respectively, and orthographic projections of two fourth gaps on the substrate are located on two opposite sides of an orthographic projection of the first wire on the substrate.

In an embodiment, the gate driving circuit includes a start transistor, a pull-down transistor and a connection node, and an output end of the start transistor and an input end of the pull-down transistor are respectively connected to the connection node; the third signal line is electrically connected to a gate of the start transistor of the starting row gate driving circuit, and a signal transmitted by the second signal line and a signal transmitted by the first signal line transmit are the same; the driving circuit layer further includes a plurality of second wires, an end of each of the plurality of second wires is connected to the second signal line, and the other end of each of the plurality of second wires is connected to a gate of the pull-down transistor of the gate driving circuit; and the second wire corresponding to the starting row gate driving circuit includes a third sub-wire and a fourth sub-wire, a fifth gap is provided between the third sub-wire and the fourth sub-wire, an end portion of the third sub-wire away from the fifth gap is connected to the gate driving circuit, and an end portion of the fourth sub-wire away from the fifth gap is connected to the gate of the pull-down transistor.

In an embodiment, a width of the first signal line is greater than a width of the second signal line.

In an embodiment, the driving circuit layer further includes a plurality of sixth signal lines located between the first signal line and the second signal line.

According to a second aspect of embodiments of the present disclosure, a display substrate is provided, including: the array substrate described above and a light-emitting structure layer located on a side of the array substrate away from the substrate. The display substrate includes a display region corresponding to the driving region of the array substrate, and the light-emitting structure layer includes a plurality of sub-pixels located in the display region.

In an embodiment, the display substrate further includes a color filter layer located on a side of the light-emitting structure layer away from the substrate, and the light-emitting structure layer includes liquid crystal molecules.

According to a second aspect of embodiments of the present disclosure, a display device is provided, including the display substrate described above.

### BRIEF DESCRIPTION OF THE DRAWINGS

FIG. 1 shows a schematic structural diagram of an array substrate provided by an exemplary embodiment of the present disclosure.

FIG. 2 shows a schematic structural diagram of a part of a driving circuit layer of an array substrate located in a first frame region provided by an exemplary embodiment of the present disclosure.

FIG. 3 shows a circuit schematic diagram of a gate driving circuit provided by an exemplary embodiment of the present disclosure.

FIG. 4 shows a partial cross-sectional view of an array substrate provided by an exemplary embodiment of the present disclosure.

FIG. 5 shows a partial cross-sectional view of an array substrate provided by another exemplary embodiment of the present disclosure.

FIG. 6 shows a partial cross-sectional view of an array substrate provided by yet another exemplary embodiment of the present disclosure.

FIG. 7 shows a partial structural diagram of the driving circuit layer of the array substrate shown in FIG. 2.

FIG. 8 shows a partial structural diagram of the driving circuit layer of the array substrate shown in FIG. 2.

FIG. 9 shows a partial cross-sectional view of an array substrate provided by yet another exemplary embodiment of the present disclosure.

FIG. 10 shows a schematic diagram of an electrical connection between a flexible circuit board and a driving chip provided by an exemplary embodiment of the present disclosure.

FIG. 11 shows a partial cross-sectional view of an array substrate provided by yet another exemplary embodiment of the present disclosure.

FIG. 12 shows a partial cross-sectional view of a display substrate provided by an exemplary embodiment of the present disclosure.

FIG. 13 shows a schematic structural diagram of a display substrate provided by an exemplary embodiment of the present disclosure.

### DETAILED DESCRIPTION OF EMBODIMENTS

Exemplary embodiments will be described in detail here, and examples of the exemplary embodiments are illustrated in the accompanying drawings. When the following descriptions refer to the accompanying drawings, the same numbers in different drawings represent the same or similar elements unless otherwise indicated. The embodiments described in the following exemplary embodiments do not represent all embodiments consistent with the present disclosure. On the contrary, they are only examples of devices and methods consistent with some aspects of the present disclosure as detailed in the appended claims.

The terms used in the present disclosure are only for the purpose of describing specific embodiments and are not intended to limit the present disclosure. The singular forms “a”, “the” and “said” used in the present disclosure and the appended claims are also intended to include plural forms, unless the context clearly indicates otherwise. It should also be understood that the term “and/or” used herein refers to and includes any or all possible combinations of one or more related listed items.

It should be understood that although terms such as first, second, and third may be used in the present disclosure to describe various information, such information should not be limited by these terms. These terms are merely used to distinguish the same type of information from each other. For example, without departing from the scope of the present disclosure, the first information may also be referred to as the second information, and similarly, the second information may also be referred to as the first information. Depending on the context, the word “if” as used here may be interpreted as “when . . . ” , “at the time of . . . ” or “in response to determining”.

Embodiments of the present disclosure provide an array substrate, a display substrate and a display device. The array substrate, the display substrate and the display device in embodiments of the present disclosure will be described in detail below with reference to the accompanying drawings. In case of no conflict, the features in the following embodiments may be supplemented or combined with each other.

In order to save manufacturing costs of display panels, a smaller-sized display panel may share a mask for manufacturing a driving circuit layer with a larger-sized display panel. For example, a 58.5-inch display panel and a 65-inch display panel share the mask for manufacturing the driving circuit layer. After the manufacturing of the driving circuit layer of the smaller-sized display panel is completed, a redundant part of the driving circuit layer needs to be cut off, resulting in a starting row gate driving circuit being cut off. The starting row gate driving circuit in the obtained display substrate may not be electrically connected to a driving chip, causing failure of the starting row gate driving circuit and affecting a normal display of the display panel.

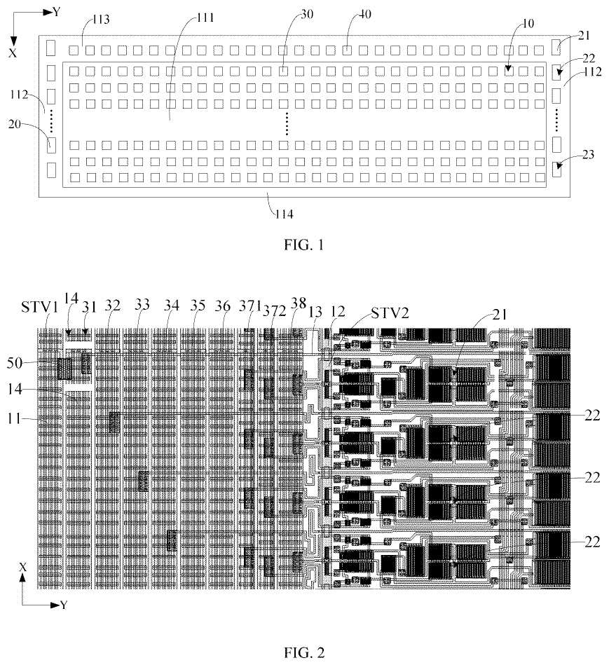

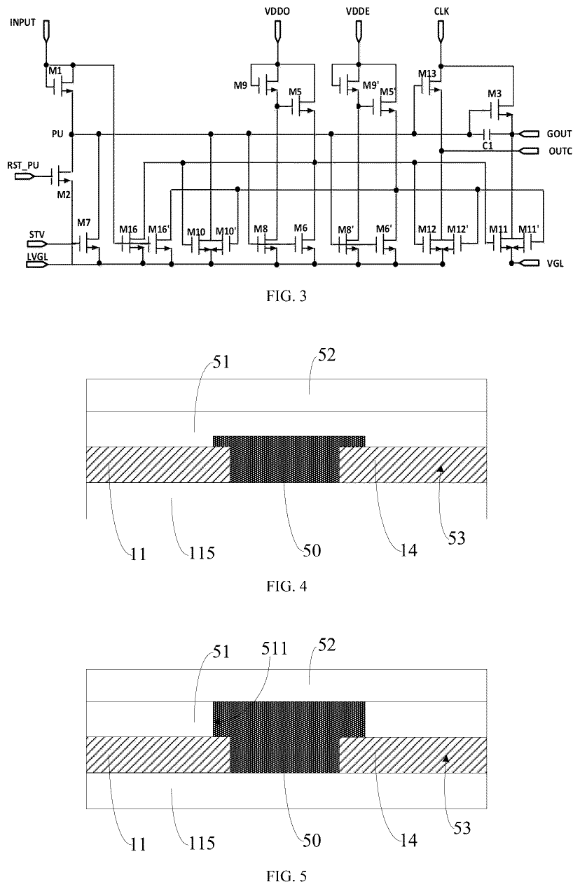

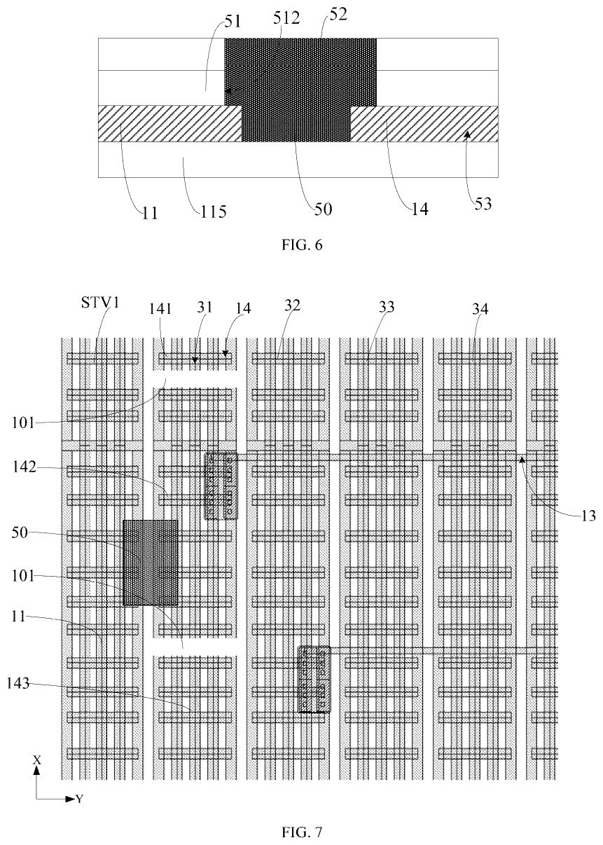

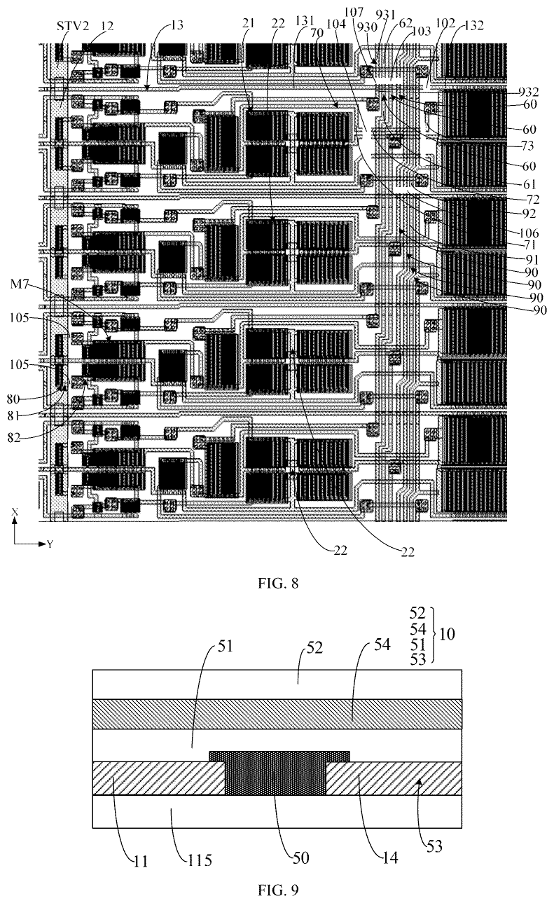

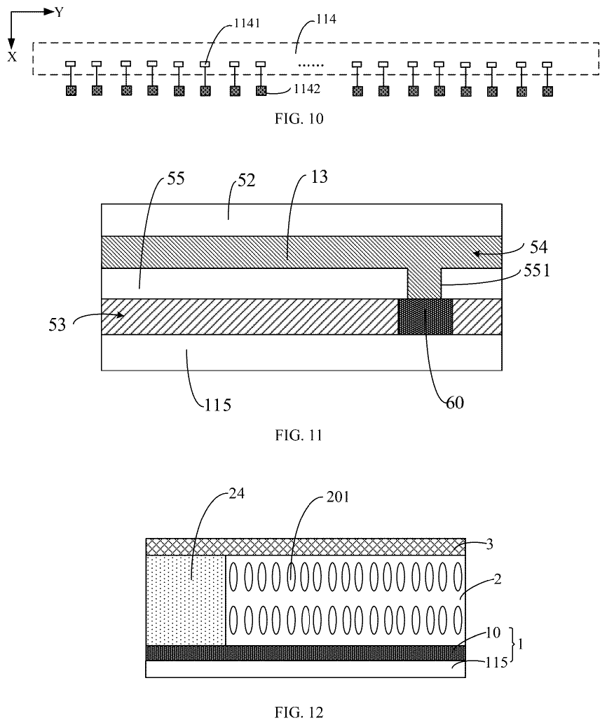

Embodiments of the present disclosure provide an array substrate. The array substrate is used for a display substrate, and the display substrate includes a display region. As shown in FIG. 1, the array substrate includes a driving region 111 corresponding to the display region of the display substrate and a first frame region 112 located on a side of the driving region 111 and extending in a first direction X. The array substrate includes a substrate and a driving circuit layer located on a side of the substrate. As shown in FIG. 9, the array substrate includes a substrate 115 and a driving circuit layer 10 located on a side of the substrate 115. As shown FIG. 1, the driving circuit layer 10 includes a plurality of gate driving circuits 20 located in the first frame region 112 and a plurality of pixel circuits 30 located in the driving region 111.

As shown in FIG. 2, the driving circuit layer 10 further includes a first signal line 11, a second signal line 12 and a third signal line 13 located in the first frame region 112. The first signal line 11 and the second signal line 12 extend in the first direction X, the third signal line 13 extends in a second direction Y, and the second direction Y intersects the first direction X. The first signal line 11 is located on a side of the second signal line 12 away from the driving region 111. The plurality of gate driving circuits 20 include a dummy gate driving circuit 21 and a starting row gate driving circuit 22. An end of the first signal line 11 is electrically connected to the third signal line 13, and the other end of the first signal line 11 is used for electrical connection with a driving chip, and the driving chip provides a driving signal to the starting row gate driving circuit 22. The third signal line 13 is electrically connected to the dummy gate driving circuit 21 and is electrically connected to the starting row gate driving circuit 22.

In the array substrate provided by embodiments of the present disclosure, the starting row gate driving circuit is electrically connected to the driving chip through the third signal line, and the driving chip may provide a driving signal to the starting row gate driving circuit through the third signal line, so that the starting row gate driving circuit may work normally, ensuring the normal display of the display substrate. The third signal line electrically connected to the dummy gate driving circuit is used to realize the electrical connection between the driving chip and the starting row gate driving circuit, and there is no need to manufacture additional connecting lines, which contributes to simplifying a manufacturing process of the display substrate.

In an embodiment, as shown in FIG. 1, the frame region of the array substrate may include two oppositely disposed first frame regions 112, and the array substrate further includes a second frame region 113 and a third frame region 114 that are oppositely disposed and extend in a same direction. The second frame region 113 and the third frame region 114 extend in the second direction Y. The first direction X and the second direction Y may be perpendicular to each other. For example, the first direction X is a column direction, and the second direction Y is a row direction. Each of the two first frame regions 112 may be provided with the gate driving circuit 20. The driving circuit layer 10 may further include a plurality of dummy pixel circuits 40 located in the second frame region 113. The third frame region 114 may be provided with fan-out lines, a flexible circuit board, etc. The flexible circuit board may be electrically connected to the driving chip, and the third signal line 13 may be electrically connected to the driving chip through being electrically connected to the flexible circuit board. As shown in FIG. 10, the third frame region 114 may be provided with a flexible circuit board 1141, and the flexible circuit board 1141 may be electrically connected to the driving chip 1142.

In an embodiment, as shown in FIG. 1, the plurality of gate driving circuits 20 of the array substrate may be disposed in the first direction X, the plurality of gate driving circuits 20 further include a non-starting row gate driving circuit 23, and the non-starting row gate driving circuit 23 may be located on a side of the starting row gate driving circuit 22 away from the dummy gate driving circuit 21. The dummy gate driving circuit 21 refers to a gate driving circuit that does not provide a gate driving signal to the pixel circuit, and the dummy gate driving circuit 21 may be electrically connected to a dummy pixel circuit 40. The dummy pixel circuit 40 refers to a pixel circuit that does not work. The starting row gate driving circuit 22 operates after receiving the driving signal provided by the driving chip, and outputs a cascaded signal to the non-starting row gate driving circuit 23 cascaded therewith. The number of starting row gate driving circuits 22 may be one or more, for example, the number of starting row gate driving circuits 22 may be three.

In an embodiment, as shown in FIG. 9, the driving circuit layer 10 includes a first conductive layer 53 and a second conductive layer 54 located on a side of the first conductive layer 53 away from the substrate 115. Each of the pixel circuit 30 and the gate driving circuit 20 may include a thin film transistor, and the thin film transistor includes an active layer, a gate electrode, a source electrode, and a drain electrode. The gate electrode may be located on a side of the active layer facing the substrate 115, and the source electrode and the drain electrode may be located on a side of the active layer away from the substrate 115. For example, the gate electrode may be located in the first conductive layer 53, and the source electrode and the drain electrode may be located in the second conductive layer 54.

As shown in FIG. 2, the driving circuit layer 10 may further include a plurality of signal lines located in the first frame region 112 and extending in the first direction X. In a direction approaching the gate driving circuit 20, the plurality of signal lines extending in the first direction X are sequentially disposed as a start control signal line STV1, a plurality of clock signal lines 31-36, a high-level power signal line 371, a high-level power signal line 372, a low-level power signal line 38, and a start control signal line STV2. The start control signal line STV1 and the start control signal line STV2 may transmit the same signal.

In an embodiment, as shown in FIG. 3, the gate driving circuit 20 includes a capacitor C1 and transistors M1, M2, M3, M5, M5′, M6, M6′, M7, M8, M8′, M9, M9′, M10, M10′, M11, M11′, M12, M12′, M13, M16, M16′. The gate driving circuit 20 further includes input ports INPUT, RST_PU, STV, VGL, LVGL, VDDO, VDDE, CLK, and output ports GOUT, OUTC. A connection relationship between the capacitor C1, the above-mentioned transistors, the input ports, and the output ports are as shown in FIG. 3. The gate driving circuit 20 further includes a connection node PU. The transistor M1 is a start transistor, and the transistor M7 is a pull-down transistor. An input end and a gate of the start transistor M1 are respectively connected to the input port INPUT, an output end of the start transistor MI is connected to the connection node PU, an input end of the pull-down transistor M7 is connected to the connection node PU, a gate of the pull-down transistor M7 is connected to the input port STV, and an output end of the pull-down transistor M7 is connected to the low-level power signal input port LVGL.

In an embodiment, the start transistor MI of the starting row gate driving circuit 22 is connected to the first signal line 11. Specifically, the first signal line 11 may be electrically connected to the gate of the start transistor MI of the starting row gate driving circuit 22, and provide a driving signal to the gate of the start transistor M1. In some embodiments, the first signal line 11 may be the start control signal line STV1, which provides a start control signal to the gate of the start transistor M1 of the starting row gate driving circuit 22 to turn on the start transistor M1.

In an embodiment, the pull-down transistor M7 of the gate driving circuit 20 is connected to the second signal line 12. Specifically, the second signal line 12 may be electrically connected to the gate of the pull-down transistor M7 of the starting row gate driving circuit 22, providing a start control signal to the gate of the pull-down transistor M7 to turn on the pull-down transistor M7, such that the pull-down transistor M7 pulls down a level of the connection node PU. In some embodiments, the second signal line 12 may be the start control signal line STV2.

In an embodiment, the third signal line 13 is a clock signal line connected to the input port CLK of the dummy gate driving circuit 21. Since the start transistor M1 of the dummy gate driving circuit 21 is not connected to the third signal line 13, and may not receive the driving signal provided by the driving chip, the dummy gate driving circuit 21 may not be started to drive the dummy pixel circuit 40 to work.

In an embodiment, the first signal line 11 and the second signal line 12 transmit the same signal. As shown in FIG. 2, a width of the first signal line 11 is greater than a width of the second signal line 12. If a laser process is used to melt the third signal line 13 and electrically connect the third signal line 13 with the second signal line 12, due to the small width of the second signal line 12, the melted third signal line 13 may be easily electrically connected to a signal line adjacent to the second signal line 12, resulting in a short circuit. The first signal line 11 has a larger width, which may avoid the problem of being electrically connected to a signal line adjacent to the fourth signal line 14 when the first signal line 11 is connected to the fourth signal line 14.

In an embodiment, as shown in FIG. 2, FIG. 4 to FIG. 6, and FIG. 9, the driving circuit layer 10 further includes a fourth signal line 14 and a lapping portion 50, the fourth signal line 14 is adjacent to the first signal line 11, disposed in the same layer as the first signal line 11, and extends in the same direction as the first signal line 11. The fourth signal line 14 is connected to the third signal line 13, and the lapping portion 50 is lapped with the first signal line 11 and the fourth signal line 14, respectively. In this way, the first signal line 11 is electrically connected to the third signal line 13 through the lapping portion 50 and the fourth signal line 14 in sequence.

In an embodiment, as shown in FIG. 4 to FIG. 6 and FIG. 9, the driving circuit layer 10 includes a first conductive layer 53, a first insulating layer 51 located on a side of the first conductive layer 53 away from the substrate 115, a second conductive layer 54 located on a side of the first insulating layer 51 away from the substrate 115, and a second insulating layer 52 located on a side of the second conductive layer 54 away from the substrate 115. The start control signal line STV1, the plurality of clock signal lines 31-36, the high-level power signal line 371, the high-level power signal line 372, the low-level power signal line 38, and the start control signal line STV2 may all be located in the first conductive layer 53, and the third signal line 13 may be located in the second conductive layer 54.

In an embodiment, a material of the lapping portion 50 may be tungsten, and the lapping portion 50 may be formed by depositing tungsten. Tungsten has high stability and is not easily oxidized, which may prevent the lapping portion 50 from being oxidized to affect an electrical connection effect between the lapping portion 50 and the first signal line 11 and the fourth signal line 14. Alternatively, the lapping portion 50 may be formed by coating silver.

In an embodiment, as shown in FIG. 4, the first signal line 11 and the fourth signal line 14 are located in the first conductive layer 53, and the lapping portion 50 is located on a side of the first insulating layer 51 facing the substrate 115. The lapping portion 50 is partially located between the first signal line 11 and the fourth signal line 14, and partially located on a side of the first conductive layer 53 away from the substrate 115. In this embodiment, the lapping portion 50 is formed after the first conductive layer 53 is formed and before the first insulating layer 51 is formed. Both the first insulating layer 51 and the second insulating layer 52 cover the lapping portion 50, which may effectively prevent water and oxygen from invading the lapping portion 50, and contribute to improving a reliability of the array substrate.

In another embodiment, as shown in FIG. 5, the first signal line 11 and the fourth signal line 14 are located in the first conductive layer 53, the first insulating layer 51 is provided with a first through hole 511, and the lapping portion 50 is located on a side of the second insulating layer 52 facing the substrate 115 and is located in the first through hole 511. The lapping portion 50 is partially located between the first signal line 11 and the fourth signal line 14, and partially located on a side of the first conductive layer 53 away from the substrate 115. In this embodiment, the lapping portion 50 is formed after the first insulating layer 51 is formed and before the second insulating layer 52 is formed. The second insulating layer 52 covers the lapping portion 50, which may effectively prevent water and oxygen from invading the lapping portion 50, and contribute to improving the reliability of the array substrate.

In yet another embodiment, as shown in FIG. 6, the first signal line 11 and the fourth signal line 14 are located in the first conductive layer 53, the driving circuit layer 10 is provided with a second through hole 512 penetrating the first insulating layer 51 and the second insulating layer 52, and the lapping portion 50 is located in the second through hole 512. The lapping portion 50 is partially located between the first signal line 11 and the fourth signal line 14, and partially located on a side of the first conductive layer 53 away from the substrate 115. In this embodiment, the lapping portion 50 is formed after the second insulating layer 52 is formed.

In an embodiment, as shown in FIG. 7, the fourth signal line 14 includes a first sub-signal line 141, a second sub-signal line 142, and a third sub-signal line 143 disposed in the first direction X. A first gap 101 is provided between the second sub-signal line 142 and the first sub-signal line 141, and between the second sub-signal line 142 and the third sub-signal line 143, respectively. The second sub-signal line 142 is lapped with the lapping portion 50 and is connected to the third signal line 13. With such configuration, the second sub-signal line 142 is separated from the first sub-signal line 141 and the third sub-signal line 143, such that signals of the first sub-signal line 141 and the third sub-signal line 143 are not transmitted to the second sub-signal line 142, which may reduce interference with the signal provided by the first signal line 11 to the starting row gate driving circuit 22 through the second sub-signal line 142. In some embodiments, a laser etching process may be used to cut the fourth signal line 14 after the fourth signal line 14 is formed.

In an embodiment, as shown in FIG. 8, the third signal line 13 includes a fourth sub-signal line 131 and a fifth sub-signal line 132 located on a side of the fourth sub-signal line 131 away from the first signal line 11. A second gap 102 is provided between the fourth sub-signal line 131 and the fifth sub-signal line 132, and an end portion of the fourth sub-signal line 131 adjacent to the second gap 102 is electrically connected to the starting row gate driving circuit 22. With such configuration, the third signal line 13 is prevented from receiving the signal from the driving chip and thus interfering with the driving signal provided by the first signal line 11 to the starting row gate driving circuit 22 through the third signal line 13. In some embodiments, a laser etching process may be used to cut the third signal line 13 after the third signal line 13 is formed.

In some embodiments, the third signal line 13 is located in the second conductive layer 54, and an orthographic projection of the second gap 102 on the substrate 115 does not overlap with an orthographic projection of the first conductive layer 53 on the substrate 115. With such configuration, in the process of cutting the third signal line 13 by using the laser etching process, it may be prevented that the energy of laser acts on the first conductive layer 53 to melt the first conductive layer 53, such that the first conductive layer 53 is electrically connected to the third signal line 13, or two adjacent conductive structures in the first conductive layer 53 are electrically connected, thereby affecting performance of the display substrate.

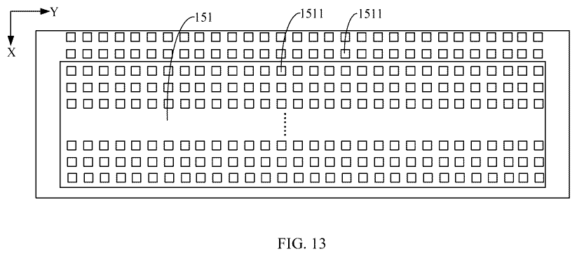

In an embodiment, as shown in FIG. 8, the driving circuit layer 10 further includes a first wire 60. An end of the first wire 60 is connected to the third signal line 13, and the other end of the first wire 60 is electrically connected to the starting row gate driving circuit 22, specifically, to the gate of the start transistor M1 of the starting row gate driving circuit 22. In an embodiment, as shown in FIG. 11, the array substrate further includes an insulating layer 55 located between the first wire 60 and the third signal line 13. The first wire 60 is electrically connected to the third signal line 13 through an opening 551 on the insulating layer 55. An orthographic projection of the first wire 60 on the substrate 115 overlaps with an orthographic projection of the third signal line 13 on the substrate 115. With such configuration, the third signal line 13 may be directly connected to the first wire 60 through the opening 551 without other switching structures, which contributes to simplifying the structure of the display substrate. In an embodiment, the first wire 60 may be located in the first conductive layer 53, the third signal line 13 may be located in the second conductive layer 54, and the insulating layer 55 may be the first insulating layer 51.

In an embodiment, as shown in FIG. 8, when there are a plurality of starting row gate driving circuits 22, first wires 60 are in one-to-one correspondence with the starting row gate driving circuits 22. An end of each of the first wires 60 is electrically connected to the third signal line 13, and the other end of each of the first wires 60 is electrically connected to the start transistor M1 of a corresponding starting row gate driving circuit 22.

In some embodiments, after the third signal line 13 is formed, a laser etching process may be used to form the opening 551 on the insulating layer 55 between the first wire 60 and the third signal line 13, and the opening 551 exposes a part of the first wire 60. During laser etching, the third signal line 13 melts and enters the opening 551 to form a conductive portion, such that the third signal line 13 is connected to the first wire 60 through the conductive portion located in the opening 551.

In an embodiment, as shown in FIG. 8, the first wire 60 includes a first sub-wire 61 and a second sub-wire 62. An end of the first sub-wire 61 is connected to the third signal line 13, and the other end of the first sub-wire 61 is electrically connected to the starting row gate driving circuit 22. The second sub-wire 62 is located on a side of the first sub-wire 61 away from the starting row gate driving circuit 22. A third gap 103 is provided between the first sub-wire 61 and the second sub-wire 62. With such configuration, an interference on the signal transmitted by the third signal line 13 to the starting row gate driving circuit 22 may be further reduced.

In an embodiment, the driving circuit layer 10 further includes at least one fifth signal line 70; the fifth signal line 70 extends in the second direction Y and is electrically connected to the dummy gate driving circuit 21. The fifth signal line 70 includes a sixth sub-signal line 71, a seventh sub-signal line 72, and an eighth sub-signal line 73 that are disposed in the second direction Y. A fourth gap 104 is provided between the seventh sub-signal line 72 and the sixth sub-signal line 71, and between the seventh sub-signal line 72 and the eighth sub-signal line 73, respectively. Orthographic projections of the two fourth gaps 104 on the substrate 115 are located on two opposite sides of the orthographic projection of the first wire 60 on the substrate 115. With such configuration, a signal of the fifth signal line 70 may be prevented from interfering with the signal transmitted by the first wire 60 to the starting row gate driving circuit 22. The fifth signal line 70 is located in the second conductive layer 54, and the first wire 60 is located in the first conductive layer 53. The orthographic projections of the two fourth gaps 104 on the substrate 115 are located on two opposite sides of the orthographic projection of the first wire 60 on the substrate 115, which may prevent the laser from acting on the first wire 60 during the laser etching process for cutting the fifth signal line 70, thereby avoiding an electrical connection between the first wire 60 and adjacent signal lines or between the first wire 60 and the fifth signal line 70.

In an embodiment, as shown in FIG. 8, the driving circuit layer 10 further includes a plurality of second wires 80. An end of each of the plurality of second wires 80 is connected to the second signal line 12, and the other end of each of the plurality of second wires 80 is connected to the gate of the pull-down transistor M7 of one of the gate driving circuits 20. That is, the second signal line 12 provides a signal to the gate of the pull-down transistor M7 through the second wire 80.

In an embodiment, as shown in FIG. 8, the second wire 80 corresponding to the starting row gate driving circuit 22 includes a third sub-wire 81 and a fourth sub-wire 82. A fifth gap 105 is provided between the third sub-wire 81 and the fourth sub-wire 82. An end portion of the third sub-wire 81 away from the fifth gap 105 is connected to the second signal line 12, and an end portion of the fourth sub-wire 82 away from the fifth gap 105 is connected to the gate of the pull-down transistor M7. Since the array substrate provided in embodiments of the present disclosure shares the mask for manufacturing the driving circuit layer with a larger-sized array substrate, the starting row gate driving circuit 22 of the array substrate provided in embodiments of the present disclosure corresponds to the non-starting row gate driving circuit of the larger-sized array substrate, resulting in the gate of the pull-down transistor M7 of the starting row gate driving circuit 22 of the array substrate provided in embodiments of the present disclosure being electrically connected to the second signal line 12. By dividing the second wire 80 into the third sub-wire 81 and the fourth sub-wire 82, the gate of the pull-down transistor M7 of the starting row gate driving circuit 22 of the small-sized array substrate does not receive the signal transmitted by the second signal line 12, and the pull-down transistor M7 is not turned on, which may ensure the normal operation of the starting row gate driving circuit 22.

In an embodiment, as shown in FIG. 8, the driving circuit layer 10 further includes a plurality of third wires 90. The third wire 90 is electrically connected to the gate of the start transistor M1 of the non-starting row gate driving circuit 23, and is used to transmit a cascaded signal to the gate of the start transistor M1 of the non-starting row gate driving circuit 23. Since the array substrate provided in embodiments of the present disclosure shares the mask for manufacturing the driving circuit layer with a larger-sized array substrate, in the larger-sized array substrate, an end portion of the third wire 90 away from the corresponding start transistor M1 is connected to the output end OUTC of a previous-stage gate driving circuit. After the array substrate provided in embodiments of the present disclosure is manufactured, a part of the gate driving circuit needs to be cut off, the end portion of the third wire 90 away from the corresponding start transistor M1 is cut off, and the gate driving circuit corresponding to the third wire 90 needs to be electrically connected to the previous-stage gate driving circuit using a new wire.

In an embodiment, as shown in FIG. 8, the third wire 90 includes a fifth sub-wire 91 and a sixth sub-wire 92, and a sixth gap 106 is provided between the fifth sub-wire 91 and the sixth sub-wire 92. With such configuration, the interference on the signal transmitted by the third signal line 13 to the starting row gate driving circuit 22 may be further reduced.

In an embodiment, as shown in FIG. 8, the driving circuit layer 10 further includes a fourth wire 930. The fourth wire 930 includes a seventh sub-wire 931 and an eighth sub-wire 932, a seventh gap 107 is provided between the seventh sub-wire 931 and the eighth sub-wire 932, and an end portion of the eighth sub-wire 932 away from the seventh gap 107 is electrically connected to the dummy gate driving circuit 21. In the larger-sized array substrate, the dummy gate driving circuit is a non-starting row gate driving circuit, and the fourth wire 930 is used to connect the non-starting row gate driving circuit to the output end OUTC of the previous-stage gate driving circuit, thereby transmitting a cascaded signal to the non-starting row gate driving circuit. In embodiments of the present disclosure, the fourth wire 930 does not need to provide a cascaded signal to the dummy gate driving circuit. Cutting the fourth wire 930 into two parts may further reduce the interference on the signal transmitted by the third signal line 13 to the starting row gate driving circuit 22.

In an embodiment, as shown in FIG. 2, the driving circuit layer 10 further includes a plurality of sixth signal lines located between the first signal line 11 and the second signal line 12. When the first signal line 11 is the start control signal line STV1 and the second signal line 12 is the start control signal line STV2, the plurality of sixth signal lines include the clock signal lines 31-36, the high-level power signal line 371, the high-level power signal line 372, and the low-level power signal line 38.

Embodiments of the present disclosure further provide a display substrate, which includes the array substrate according to any one of the above-mentioned embodiments and a light-emitting structure layer located on a side of the array substrate away from the substrate. The display substrate includes the display region, the light-emitting structure layer includes a plurality of sub-pixels located in the display region and electrically connected to the pixel circuits located in the driving region. For example, as shown in FIG. 12, the display substrate includes an array substrate 1 and a light-emitting structure layer 2 located on a side of the array substrate 1 away from the substrate 115. The array substrate 1 is the array substrate according to any one of the above-mentioned embodiments, and includes a substrate 115 and a driving circuit layer 10 located on a side of the substrate 115. As shown in FIG. 13, the display substrate includes a display region 151, where the display region 151 corresponds to the driving region 111 of the array substrate according to any one of the above-mentioned embodiments. The light-emitting structure layer 2 includes a plurality of sub-pixels 1511 located in the display region 151 and electrically connected to the pixel circuits 30 located in the driving region 111.

In an embodiment, the light-emitting structure layer 2 further includes a plurality of sub-pixels located in the second frame region, and the plurality of sub-pixels are electrically connected to the dummy gate driving circuit. When the display substrate is in a display state, these sub-pixels do not emit light.

In an embodiment, as shown in FIG. 12, the display substrate further includes a color filter layer 3 located on a side of the light-emitting structure layer 2 away from the substrate 115, and the light-emitting structure layer 2 includes liquid crystal molecules 201. That is, the display substrate is a liquid crystal display substrate.

In an embodiment, as shown in FIG. 12, the display substrate further includes a frame sealant 24 located between the array substrate 1 and the color filter layer 3, and the frame sealant 24 surrounds the liquid crystal molecules 201. The frame sealant 24 may prevent the liquid crystal molecules 201 from flowing out of the display region 151 and also contribute to improving a packaging performance of the display substrate.

Embodiments of the present disclosure further provide a display device, where the display device includes the display substrate according to any one of the above-mentioned embodiments.

In some embodiments, the display device further includes a housing, and the display substrate is embedded in the housing.

The display device provided in embodiments of the present disclosure may be any appropriate display device, including but not limited to a mobile phone, a tablet computer, a television, a monitor, a notebook computer, a digital photo frame, a navigator, an e-book, and any other product or component with a display function.

It should be noted that in the accompanying drawings, dimensions of layers and regions may be exaggerated for clarity of illustration. Moreover, it may be understood that when an element or layer is referred to as being “on” another element or layer, it may be directly on the another element, or an intermediate layer may exist. In addition, it may be understood that when an element or layer is referred to as being “under” another element or layer, it may be directly under the another element, or one or more intermediate layers or elements may exist. In addition, it may also be understood that when a layer or element is referred to as being “between” two layers or two elements, it may be the only layer between the two layers or two elements, or one or more intermediate layers or elements may also exist. Throughout the specification, similar reference signs indicate similar elements.

Those skilled in the art will easily conceive of other embodiments of the present disclosure after considering the specification and practicing the contents disclosed here. The present disclosure is intended to cover any variations, uses, or adaptive changes of the present disclosure. These variations, uses, or adaptive changes follow the general principles of the present disclosure and include common knowledge or conventional technical means in the technical field not disclosed in the present disclosure. The specification and embodiments are only regarded as exemplary, and the true scope and spirit of the present disclosure are indicated by the following claims.

It should be understood that the present disclosure is not limited to the precise structures that have been described above and shown in the drawings, and various modifications and changes may be made without departing from the scope of the present disclosure. The scope of the present disclosure is only limited by the appended claims.

1. An array substrate, comprising a driving region and a first frame region located on a side of the driving region and extending in a first direction, wherein the array substrate comprises:
a substrate; and
a driving circuit layer on a side of the substrate, comprising:
a plurality of gate driving circuits in the first frame region, wherein the plurality of gate driving circuits comprise a dummy gate driving circuit and a starting row gate driving circuit;
a first signal line and a second signal line, wherein the first signal line and the second signal line extend in the first direction, and the first signal line is located on a side of the second signal line away from the driving region; and
a third signal line extending in a second direction, wherein the second direction intersects the first direction, an end of the first signal line is electrically connected to the third signal line, the other end of the first signal line is configured to be electrically connected to a driving chip, the driving chip provides a driving signal to the starting row gate driving circuit, the third signal line is electrically connected to the dummy gate driving circuit and is electrically connected to the starting row gate driving circuit.

2. The array substrate according to claim 1, wherein the driving circuit layer further comprises:
a fourth signal line adjacent to the first signal line, the fourth signal line is disposed in a same layer and extends in a same direction as the first signal line, and the fourth signal line is connected to the third signal line; and
a lapping portion overlapped with the first signal line and the fourth signal line, respectively.

3. The array substrate according to claim 2, wherein,
the driving circuit layer comprises:
a first conductive layer;
a first insulating layer located on a side of the first conductive layer away from the substrate;
a second conductive layer located on a side of the first insulating layer away from the substrate; and
a second insulating layer located on a side of the second conductive layer away from the substrate, and
the first signal line and the fourth signal line are located in the first conductive layer, and the lapping portion is located on a side of the first insulating layer facing the substrate.

4. The array substrate according to claim 2, wherein,
the driving circuit layer comprises:
a first conductive layer;
a first insulating layer located on a side of the first conductive layer away from the substrate;
a second conductive layer located on a side of the first insulating layer away from the substrate; and
a second insulating layer located on a side of the second conductive layer away from the substrate, and
the first signal line and the fourth signal line are located in the first conductive layer, the first insulating layer is provided with a first through hole, and the lapping portion is located on a side of the second insulating layer facing the substrate and is located in the first through hole.

5. The array substrate according to claim 2, wherein,
the driving circuit layer comprises:
a first conductive layer;
a first insulating layer located on a side of the first conductive layer away from the substrate;
a second conductive layer located on a side of the first insulating layer away from the substrate; and
a second insulating layer located on a side of the second conductive layer away from the substrate, and
the first signal line and the fourth signal line are located in the first conductive layer, the driving circuit layer is provided with a second through hole penetrating the first insulating layer and the second insulating layer, and the lapping portion is located in the second through hole.

6. The array substrate according to claim 2, wherein,
the fourth signal line comprises a first sub-signal line, a second sub-signal line and a third sub-signal line disposed in the first direction; and
a first gap is provided between the second sub-signal line and the first sub-signal line and between the second sub-signal line and the third sub-signal line, respectively, and the second sub-signal line is lapped with the lapping portion and is connected to the third signal line.

7. The array substrate according to claim 1, wherein,
the third signal line comprises a fourth sub-signal line and a fifth sub-signal line located on a side of the fourth sub-signal line away from the first signal line; and
a second gap is provided between the fourth sub-signal line and the fifth sub-signal line, an end portion of the fourth sub-signal line away from the second gap is electrically connected to the first signal line, and an end portion of the fourth sub-signal line adjacent to the second gap is electrically connected to the starting row gate driving circuit.

8. The array substrate according to claim 1, wherein,
the driving circuit layer further comprises a first wire, an end of the first wire is connected to the third signal line, and the other end of the first wire is electrically connected to the starting row gate driving circuit; and
the array substrate further comprises an insulating layer located between the first wire and the third signal line, the first wire is electrically connected to the third signal line through an opening on the insulating layer, and an orthographic projection of the first wire on the substrate overlaps with an orthographic projection of the third signal line on the substrate.

9. The array substrate according to claim 1, wherein,
the driving circuit layer further comprises a first wire, and the first wire comprises a first sub-wire and a second sub-wire;
an end of the first sub-wire is connected to the third signal line, and the other end of the first sub-wire is electrically connected to the starting row gate driving circuit;
the second sub-wire is located on a side of the first sub-wire away from the starting row gate driving circuit; and
a third gap is provided between the first sub-wire and the second sub-wire.

10. The array substrate according to claim 1, wherein,
the driving circuit layer further comprises a first wire and at least one fifth signal line;
an end of the first wire is connected to the third signal line, the other end of the first wire is electrically connected to the starting row gate driving circuit, and the first wire extends at least partially in the first direction;
the fifth signal line extends in the second direction and is electrically connected to the dummy gate driving circuit; and
the fifth signal line comprises a sixth sub-signal line, a seventh sub-signal line and an eighth sub-signal line disposed in the second direction, a fourth gap is provided between the seventh sub-signal line and the sixth sub-signal line and between the seventh sub-signal line and the eighth sub-signal line, respectively, and orthographic projections of two fourth gaps on the substrate are located on two opposite sides of an orthographic projection of the first wire on the substrate.

11. The array substrate according to claim 1, wherein,
the gate driving circuit comprises a start transistor, a pull-down transistor and a connection node, and an output end of the start transistor and an input end of the pull-down transistor are respectively connected to the connection node;
the third signal line is electrically connected to a gate of the start transistor of the starting row gate driving circuit, and a signal transmitted by the second signal line and a signal transmitted by the first signal line transmit are the same;
the driving circuit layer further comprises a plurality of second wires, an end of each of the plurality of second wires is connected to the second signal line, and the other end of each of the plurality of second wires is connected to a gate of the pull-down transistor of the gate driving circuit; and
the second wire corresponding to the starting row gate driving circuit comprises a third sub-wire and a fourth sub-wire, a fifth gap is provided between the third sub-wire and the fourth sub-wire, an end portion of the third sub-wire away from the fifth gap is connected to the gate driving circuit, and an end portion of the fourth sub-wire away from the fifth gap is connected to the gate of the pull-down transistor.

12. The array substrate according to claim 11, wherein a width of the first signal line is greater than a width of the second signal line.

13. The array substrate according to claim 11, wherein the driving circuit layer further comprises a plurality of sixth signal lines located between the first signal line and the second signal line

14. A display substrate, comprising: the array substrate according to claim 1; and a light-emitting structure layer located on a side of the array substrate away from the substrate,
wherein the display substrate comprises a display region corresponding to the driving region of the array substrate, and the light-emitting structure layer comprises a plurality of sub-pixels located in the display region.

15. The display substrate according to claim 14, wherein the display substrate further comprises a color filter layer located on a side of the light-emitting structure layer away from the substrate, and the light-emitting structure layer comprises liquid crystal molecules.

16. A display device, comprising the display substrate according to claim 14.
